(19) United States
(12) Patent Application Publication
(10) Pub. No.: US 2007/0170534 A1
(43) Pub. Date: Jul. 26, 2007

(54) Optical sensing apparatus with a noise interference rejection function

(75) Inventors: Wen-Hung Su, Taipei Hsien (TW); Hsueh-Ping Chen, Hsin-Tien (TW)

Correspondence Address: BIRCH STEWART KOLASCH & BIRCH, PO BOX 747, FALLS CHURCH, VA, 22040-0747, US

(73) Assignee: LITE-ON SEMICONDUCTOR CORP.

(21) Appl. No.: 11/335,627

(22) Filed: Jan. 20, 2006

(51) Int. Cl. H01L 27/14

(52) U.S. Cl. 257/431

(57) ABSTRACT

An optical sensing apparatus with a signal interference rejection function is fabricated in a semiconductor chip by using a CMOS process. The optical sensing apparatus comprises an optical sensing element having a light-receiving side for receiving an optical signal from the light-receiving side and converting the optical signal into an electronic signal, and a noise-rejection layer disposed on the light-receiving side of the optical sensing element and connected to a reference ground. The optical sensing apparatus uses the noise-rejection layer for receiving noises and guiding the noises to the reference ground, so that the noises will not affect the accuracy of images, so that image quality is improved.

### BACKGROUND OF THE INVENTION

1. Field of the Invention

The present invention relates to an optical sensing apparatus with a noise interference rejection function, and more particular to an optical sensing apparatus installed on a semiconductor chip for preventing radiation noise interference and contact noise interference.

2. Description of Related Art

Traditionally, a charge-coupled device (CCD) is an image circuit element for converting optical signal into electronic signals. The scope of CCD applications is very broad and it covers monitors, transcription machines, and cameras. Although CCDs have multiple functions, its application is still limited by its high price and large chip size. To overcome the shortcomings of CCDs and reduce their cost and chip size, a CMOS photo diode and a CMOS photo BJT have been developed. Since the CMOS photo diode and CMOS photo BJT are made by a traditional semiconductor fabrication process, the cost and chip size can be greatly reduced.

Referring to FIG. 1 for the diagram view of a preferred structure of a prior art photo diode, the photo diode 10 includes a P-sub 102 and an N-well 104 disposed on the P-sub 102. Referring to FIG. 2 for the diagram view of another preferred structure of a prior art photo diode, the photo diode 12 includes an N-well 122 and a P-type layer (P+) 124 disposed on the N-well 122. Referring to FIG. 3 for the diagram view of a preferred structure of a prior art photo BJT, the photo BJT 14 includes a first P-type layer (P+) 142, an N-type layer (N+) 144 disposed on the P-type layer (P+) 142, and a second P-type layer (P+) 146 disposed on the N-type layer (N+) 144.

A photo diode used for converting light energy into electronic signals is illustrated as follows. The basic theory of a photo diode uses the production of a P-N junction current to convert an optical signal into an electronic signal. Before the energy in the form of photons is pounded onto the photo diode, an electric field exists at the P-N junction, and thus the electrons in the N-doped area will not diffuse towards the P-doped area. Similarly, the holes in the P-doped area will not move towards the N-doped area. If there is sufficient light energy is pounded onto the photo diode, such light energy will produce some electron-hole pairs which will move towards the P-N junction. When the electron-hole pairs reach the P-N junction, the electrons will flow towards the N-doped area and the holes will flow towards the P-doped area due to the influence of the electric field occurred at the P-N junction. Therefore, the energy of the incident light can be obtained by measuring the intensity of the current, and such the light energy can be converted into an electronic signal.

The photo diode can be fabricated in a semiconductor chip, and the semiconductor chip uses the properties of the photo diode to capture images. However, the image captured by the semiconductor chip is usually affected by radiation interference or contact noise interference produced by an external object or a human body. Radiation interference refers to electromagnetic interference. Both radiation interference and contact noise interference are the most important effect for the semiconductor chip. In a less serious case, the images produced by the semiconductor chip are distorted, and in a more serious case, the semiconductor chip would become damaged.

### SUMMARY OF THE INVENTION

In order to solve the foregoing shortcomings of the prior art, the present invention provides an optical sensing apparatus having a noise interference rejection function, and an optical sensing apparatus is fabricated on a semiconductor chip for preventing radiation interference and contact noise interference.

The optical sensing apparatus of the invention comprises an optical sensing element having a light-receiving side and a noise-rejection layer of a reference ground. The optical sensing element receives an optical signal from the light-receiving side and converts the optical signal into an electronic signal. The noise-rejection layer is disposed on the light-receiving side of the optical sensing element. The optical sensing apparatus of the invention directly uses the noise-rejection layer to eliminate directly the radiation interference and contact noise interference, and its purpose is to guide the interfering noises to the reference ground through the noise-rejection layer, so that the noises will not affect the accuracy of images.

### BRIEF DESCRIPTION OF THE DRAWINGS

The foregoing aspects and many of the attendant advantages in this invention will be more readily appreciated as the same becomes better understood by reference to the following detailed description, when taken in conjunction with the accompanying drawings, wherein:

FIG. 1 is a diagram view of a first preferred structure of a prior art photo diode;

FIG. 2 is a diagram view of a second preferred structure of a prior art photo diode;

FIG. 3 is a diagram view of a preferred structure of a prior art photo BJT;

FIG. 4 is a diagram view of a first preferred embodiment of the invention;

FIG. 5 is a diagram view of a second preferred embodiment of the invention;

FIG. 6 is a diagram view of a third preferred embodiment of the invention;

FIG. 7 is a diagram view of a fourth preferred embodiment of the invention;

FIG. 8 is a diagram view of a fifth preferred embodiment of the invention; and

FIG. 9 shows top views of an optical sensing apparatus with a mesh structure layer of the third, fourth, and fifth preferred embodiments of the invention.

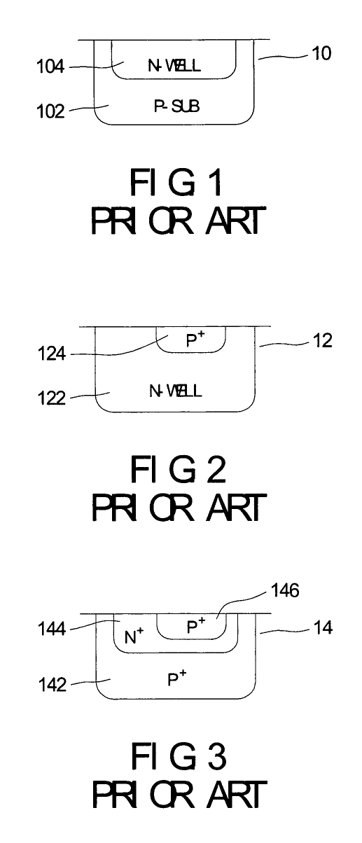

### DETAILED DESCRIPTION OF THE PREFERRED EMBODIMENTS

The present invention is illustrated with a preferred embodiment and attached drawings. However, the invention is not intended to be limited thereby.

Referring to FIG. 4 for the diagram view of a first preferred embodiment of the invention, an optical sensing apparatus 2 having a noise interference rejection function of the invention and fabricated in a semiconductor chip (not shown in the figure) by a complementary metal oxide semiconductor (CMOS) process. It comprises an optical sensing element 20 having a light-receiving side 202, and the optical sensing element 20 receives an optical signal Sm from the light-receiving side 202 and converts the optical signal Sm into an electronic signal; and a noise-rejection layer 22 disposed on light-receiving side 202 of the optical sensing element 20 and connected to a reference ground G. The optical sensing element 20 could be a photo diode or a photo BJT. The noise-rejection layer 22 is made of a polysilicon material, so that the noise-rejection layer 22 concurrently has light-transmitting and electric-conducting effects, therefore it is also known as a light-transmitting layer 22.

In the first preferred embodiment as shown in FIG. 4, the light-transmitting layer 22 is coated on the light-receiving side 202 of the optical sensing element 20. When the optical sensing element 20 is operated, the light-transmitting layer 22 can eliminate external interference signals Sn that include radiation interference and contact noise interference. In FIG. 4, the light-transmitting layer 22 is connected to the reference ground G, and thus the interference signal Sn can be guided to the reference ground G, and the optical signal Sm can pass through the light-transmitting layer 22 and shoot into the optical sensing element 20, such that the optical sensing element 20 can obtain a better image without being affected by external interference.

Referring to FIG. 5 for the second preferred embodiment of the invention, the main difference between the second preferred embodiment and the first preferred embodiment is that the light-transmitting layer 32 of the optical sensing apparatus 3 with a noise interference rejection function is embedded in the light-receiving side 302 of the optical sensing element 30. When the optical sensing element 30 is operated, the light-transmitting layer 32 can eliminate external interference signals Sn that include radiation interference and contact noise interference. In FIG. 5, the light-transmitting layer 32 is connected to the reference ground G, and thus the interference signal Sn can be guided to the reference ground G, and the optical signal Sm can pass through the light-transmitting layer 32 and shoot into the optical sensing element 30, such that the optical sensing element 30 can obtain a better image without being affected by external interference.

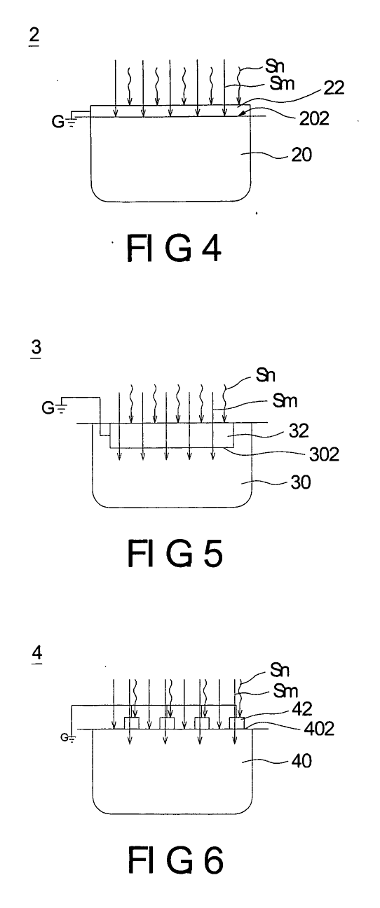

Referring to FIG. 6 for the third preferred embodiment of the invention, the main difference between the third preferred embodiment and the first preferred embodiment is that the light-transmitting layer 42 of the optical sensing apparatus 4 with a noise interference rejection function of the invention is a mesh structure layer, and the light-transmitting layer 42 is coated onto the light-receiving side 402 of the optical sensing element 40. When the optical sensing element 40 is operated, the light-transmitting layer 42 can eliminate external interference signals Sn, which include radiation interference and contact noise interference. In FIG. 6, the light-transmitting layer 42 is connected to the reference ground G, and thus the interference signal Sn can be guided to the reference ground G, and the optical signal Sm can pass through the light-transmitting layer 42 and shoot into the optical sensing element 40, such that the optical sensing element 40 can obtain a better image without being affected by external interference.

Referring to FIG. 7 for the fourth preferred embodiment of the invention, the main difference between the fourth preferred embodiment and the first preferred embodiment is that the light-transmitting layer 52 of the optical sensing apparatus 5 with a noise interference rejection function is a mesh structure layer, and the light-transmitting layer 52 is embedded in the light-receiving side 502 of the optical sensing element 50. When the optical sensing element 50 is operated, the light-transmitting layer 52 can eliminate external interference signals Sn that include radiation interference and contact noise interference. In FIG. 7, the light-transmitting layer 52 is connected to the reference ground G, and thus the interference signal Sn can be guided to the reference ground G, and the optical signal Sm can pass through the light-transmitting layer 52 and shoot into the optical sensing element 50, such that the optical sensing element 50 can obtain better images without being affected by external interference.

Referring to FIG. 8 for the fifth preferred embodiment of the invention, the main difference between the fifth preferred embodiment and the first preferred embodiment is that the noise-rejection layer 62 of the optical sensing apparatus 6 has a noise interference rejection function that is made of a metal material, and thus the noise-rejection layer 62 has the electric-conducting effect but not the light-transmitting effect, and the noise-rejection layer 62 can also be known as a metal layer 62. Furthermore, the metal layer 62 is a mesh structure layer, and the metal layer 62 is coated on the light-receiving side 602 of the optical sensing element 60. When the optical sensing element 60 is operated, the metal layer 62 can eliminate external interference signals Sn that include radiation interference and contact noise interference. In FIG. 8, the metal layer 62 is connected to the reference ground G, and thus the interference signal Sn can be guided to the reference ground G, and the optical signal Sm can shoot into the optical sensing element 60 through a penetrating hole 604 between two metal layers 62, such that the optical sensing element 60 can obtain a better image without being affected by external interference.

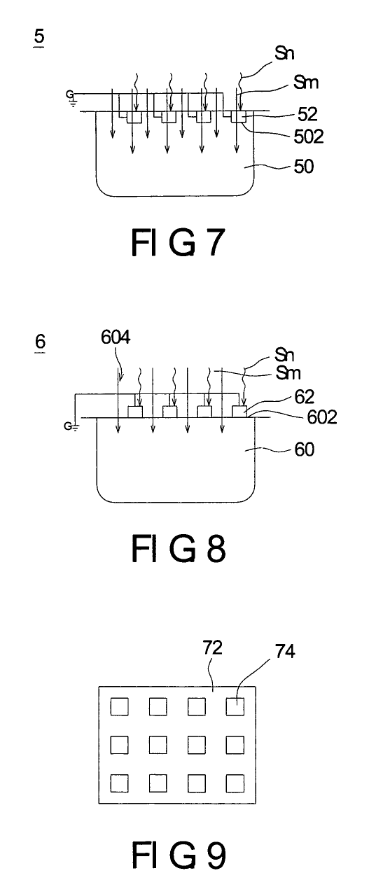

Referring to FIG. 9 for the top views of an optical sensing apparatus having a mesh structure layer according to the third, fourth, and fifth preferred embodiments of the invention, a top plate and a bottom plate of the mesh structure layer 72 separately have at least one penetrating hole 74, and the shape of these penetrating holes 74 can be circular, square, polygonal, or any other shape.

In the summation of the description above, the optical sensing apparatus has a noise interference rejection function of the invention that uses a noise-rejection layer disposed on the light-receiving side of the optical sensing element and connected to the reference ground for receiving interfering noises and guiding the noises to the reference ground, such that the noises will not affect the accuracy of images, so as to improve image quality.

While the invention has been described by means of a specification with accompanying drawings of specific embodiments, numerous modifications and variations could be made thereto by those skilled in the art without departing from the scope and spirit of the invention set forth in the claims.

What is claimed is:

1. An optical sensing apparatus with a noise interference rejection function, fabricated in a semiconductor chip and comprising:
an optical sensing element, having a light-receiving side, for receiving an optical signal from said light-receiving side and converting said optical signal into an electronic signal; and
a noise-rejection layer, disposed on said light-receiving side of said optical sensing element and connected to a reference ground.

2. The optical sensing apparatus of claim 1, wherein said optical sensing element is a photo diode.

3. The optical sensing apparatus of claim 1, wherein said optical sensing element is a photo BJT.

4. The optical sensing apparatus of claim 1, wherein said noise-rejection layer is a light-transmitting layer.

5. The optical sensing apparatus of claim 1, wherein said noise-rejection layer is coated onto said light-receiving side of said optical sensing element.

6. The optical sensing apparatus of claim 1, wherein said light-transmitting layer is embedded in said light-receiving side of said optical sensing element.

7. The optical sensing apparatus of claim 4, wherein said light-transmitting layer is made of a polysilicon material.

8. The optical sensing apparatus of claim 1, wherein said noise-rejection layer is a mesh structure layer.

9. The optical sensing apparatus of claim 8, wherein said mesh structure layer includes at least one penetrating hole.

10. The optical sensing apparatus of claim 1, wherein said optical sensing apparatus is made by a complementary metal oxide semiconductor (CMOS) process.

11. An optical sensing apparatus with a noise interference rejection function, fabricated in a semiconductor chip and comprising:
an optical sensing element, having a light-receiving side, for receiving an optical signal from said light-receiving side and converting said optical signal into an electronic signal; and
a metal layer, coated on said light-receiving side of said optical sensing element and connected to a reference ground.

12. The optical sensing apparatus of claim 11, wherein said optical sensing element is a photo diode.

13. The optical sensing apparatus of claim 11, wherein said optical sensing element is a photo BJT.

14. The optical sensing apparatus of claim 11, wherein said metal layer is a mesh structure layer.

15. The optical sensing apparatus of claim 14, wherein said mesh structure layer includes at least one penetrating hole.

16. The optical sensing apparatus of claim 11, wherein said optical sensing apparatus is made by a complementary metal oxide semiconductor process.
